(19) United States
(12) Patent Application Publication
(10) Pub. No.: US 2024/0011665 A1
(43) Pub. Date: Jan. 11, 2024

(54) Instant Heating Unit, Toilet and Instant Heating Method

(71) Applicant: LIXIL LIVING TECHNOLOGY (SUZHOU) CORPORATION, Suzhou (CN)

(72) Inventors: Peihua Yan, Suzhou (CN); Jing Zhu, Suzhou (CN); Masayuki Makino, Suzhou (CN)

(73) Assignee: LIXIL LIVING TECHNOLOGY (SUZHOU) CORPORATION, Suzhou (CN)

(21) Appl. No.: 18/025,568

(22) PCT Filed: Sep. 23, 2021
(86) PCT No.: PCT/CN2021/119803

§ 371 Date: Mar. 9, 2023

(30) Foreign Application Priority Data
Sep. 24, 2020 (CN) 202011015556.X

(51) Int. Cl. F24H 1/10; F24H 15/219

(52) U.S. Cl. CPC F24H 1/10; F24H 15/219

(57) ABSTRACT

The present invention provides an instant heating unit for heating washing water of a toilet, the instant heating unit comprising: a housing having a water inlet and a water outlet, washing water to be heated flowing into the housing through the water inlet and flowing out of the housing through the water outlet; and a heating device, the heating device being configured to be of a hollow tube shape, arranged inside the housing, and extending along the longitudinal direction of the housing; wherein an annular gap is formed between the outer surface of the heating device and the inner surface of the housing, the washing water flows into the interior of the heating device from the water inlet, flows from the interior of the heating device to the annular gap, and flows out of the water outlet through the annular gap. Due to different flows in the annular gap, vortexes or turbulent flows can be formed, so as to enhance the uniformity of heating inside the washing water and improve the consistency of the water temperature. The present invention further relates to a toilet and an instant heating method for heating washing water of a toilet by means of an instant heating unit.

### FIELD OF THE INVENTION

The present invention relates to the field of bathroom fixtures, and mainly to an instant heating unit for heating washing water of a toilet and a toilet comprising such instant heating unit. In addition, the present invention further relates to an instant heating method for heating washing water of a toilet by means of an instant heating unit.

### DESCRIPTION OF THE RELATED ART

Most of modern toilets, in particular, smart toilets, are installed with water spraying devices for cleaning people's private parts. When the weather becomes cold or according to different needs of users, water in the water spraying devices need to be heated for use. Such heating devices are typically provided with an instant heating device for heating washing water contained therein to a desired temperature within a short period, thereby achieving the effect of rapid heating.

For an instant heating device, since water is located at different positions inside a heater, the water closer to the heater body has higher temperature, while the water farther away from the heater body has lower temperature due to reasons such as thermal conductivity. As a result, the temperature of the washing water is certainly not uniform, and users using the washing function will feel uncomfortable by such hot and cold water.

To solve this problem, it is known that an instant heating unit has been provided in an prior art. A heating rod for heating washing water is provided inside the instant heating unit, and at the same time, a layer of a helical resin structure is added onto the inner wall of the housing of the instant heating unit, which is expected to cause the washing water to flow, in a helical form, through the entire length of the heating rod between the outer wall of the heating rod and the inner wall of the housing to increase the contact time with the heating rod, thereby achieving more uniform heating.

However, in this prior art, the precision of the gap between the heating rod and the helical resin structure actually cannot be guaranteed, and it is very likely that an unexpected spatial gap is created between the two. Subject to pressure, the water actually does not flow through the heating rod by strictly following the determined helical form; instead, it directly flows through the space or channel with the lowest flow resistance between the heating rod and the helical resin structure, and consequently it is impossible to guarantee that the washing water can be uniformly heated.

In addition, since the thickness of the helical resin structure on the inner wall of the housing is very small, for example, only at the mm level, the problem of poor flame-retarding effect will occur due to the small thickness of the resin when the instant heating unit is heating without water, which is extremely disadvantageous for the safety design of the whole system.

It is also known that an instant heating unit is provided in an prior art. A heating wire in the form of a spring is provided in the instant heating unit. The spring heating wire is made of a metal material, such as steel wire. In the instant heating unit, washing water flows around the spring heating wire, which increases the heating area, and at the same time, the metal causes the heating heat to be distributed uniformly, leading to a high heating efficiency. However, this prior art has a defect in that the metal, such as the steel wire, tends to have an issue of corrosion, which has adverse effects on the water quality of the washing water. On the other hand, the cost will be very high if copper wire is used.

Therefore, there is always a need in the field of toilets for an instant heating unit that provides a function of uniformly heating washing water using a simple and reliable structure.

### SUMMARY OF THE INVENTION

To achieve an instant heating effect of uniformly heating washing water using a simple structure, the present invention provides an instant heating unit for heating washing water of a toilet, the instant heating unit comprising: a housing having a water inlet and a water outlet, washing water to be heated flowing into the housing through the water inlet and flowing out of the housing through the water outlet; and a heating device, the heating device being configured to be of a hollow tube shape, arranged inside the housing, and extending along the longitudinal direction of the housing; wherein an annular gap is formed between the outer surface of the heating device and the inner surface of the housing, the washing water flows into the interior of the heating device from the water inlet, flows from the interior of the heating device to the annular gap, and flows out of the water outlet through the annular gap.

By means of flowing through the interior of the hollow tubular heating device into the annular gap between the outer surface of the heating device and the inner surface of the housing, vortexes or turbulent flows can be formed due to different flows of different portions of the washing water (for example, the center portion and the side portion close to the fixed surfaces) in the annular gap, so as to enhance the uniformity of heating inside the washing water, improve the consistency of the water temperature, and improve the washing feeling of users.

For example, an inner cavity and a longitudinal center line may be defined inside the heating device, and the washing water flows into the inner cavity. Thus, after entering via the water inlet, the washing water can directly flow into the inner cavity inside the heating device, so as to selectively perform preheating and/or obtain a large volume of storage of the washing water in the instant heating unit.

Preferably, the heating device is arranged at the center in the housing, so that the gap width of the annular gap is circumferentially distributed in a uniform manner in each cross section along the longitudinal center line. When the gap width of the annular gap is circumferentially uniform, the degree of heating of the washing water flowing in the annular gap is uniform at various circumferential positions, thereby achieving more consistent heating temperatures.

Advantageously, the annular gap comprises a narrowed section, and the gap width of the narrowed section is designed to narrow down along the longitudinal direction of the housing and towards the water inlet. In particular, the washing water can flow in the annular gap from a direction away from the water inlet to a direction toward the water inlet. By means of the narrowing annular gap, vortexes formed inside the washing water can be further thoroughly mixed, thereby achieving the goal of improving the heating uniformity.

More advantageously, the cross section of the narrowed section is designed to continuously and uniformly narrow down along the longitudinal direction and towards the water inlet. By means of the uniformly and gradually changing annular gap, the self-disturbance force of the washing water can be significantly enhanced.

Most advantageously, the size of the annular gap is designed to be small enough to enable the washing water flowing to the outlet via the narrowed section to generate vortexes. For example, the size of the annular gap is 2 to 5 mm. In this size range, the heated washing water has the most uniform and consistent temperature distribution.

In a particularly simple configuration, the heating device is arranged in such a way that the flowing direction of the washing water therein is opposite to the flowing direction thereof in the annular gap. As a result, the washing water flowing through the inner cavity of the heating device is deflected at its longitudinal end and then directly flows into the annular gap, thereby achieving the improvement of the heating efficiency by means of the compact space.

In some embodiments, the housing further comprises a transitioning opening and a water mixing section, the washing water laterally leaves, through the transitioning opening, the annular gap and enters the water mixing section, and the water mixing section is in direct communication with the water outlet. As a result, the heated washing water can, after leaving the annular gap, not directly flow out of the water outlet, but pass through a segment of mixing area, so as to improve the flexibility of channel design and increase the possibility of improving the water temperature uniformity.

In particular, a first spoiler mechanism is provided in the water mixing section, and the first spoiler mechanism comprises a baffle capable of defining a tortuous path for the washing water to flow in the water mixing section. With the provision of the tortuous flowing path, the washing water can further generate vortexes in the mixing region, and then enhance the temperature uniformity.

In addition, the instant heating unit further comprises a second spoiler mechanism, the second spoiler mechanism comprises vanes, and the washing water that leaves the inner cavity hits the vanes and flows to the annular gap. By means of the vanes, the washing water can be turned, and at the same time, the washing water flowing to the annular gap can be caused to generate vortexes or turbulent flows, thereby enhancing the heating uniformity in the annular gap.

Advantageously, the second spoiler mechanism is arranged at or close to an end of the housing of the instant heating unit that is away from the water inlet. As a result, the second spoiler mechanism can be easily attached to the housing, and realize the generation of turbulent flows in the washing water with the compact space.

In particular, the vanes of the second spoiler mechanism can be rotated. Regardless whether it is active rotation or due to impacts by the washing water, the rotatable vanes can enhance the formation of vortexes in the washing water, so as to further cause the water temperature to be uniform.

More advantageously, a water-cooling heat-conducting plate capable of contacting the washing water inside the housing is attached to the instant heating unit, and the water-cooling heat-conducting plate is used for heat dissipation for a control circuit. Therefore, the washing water can be used to cool the control circuit, thereby improving the system efficiency.

In addition, the instant heating unit comprises an independent temperature safety device, the temperature safety device comprises a temperature sensor, and when the temperature sensor detects that the temperature of the washing water exceeds a preset temperature, the temperature safety device can stop the washing water from entering the instant heating unit. The independent temperature sensor is controlled independent of a controller for controlling the heating power. Such independence can ensure that there are still temperature sensors capable of sending an alarm when the control circuit is broken down by a large current that causes the heating device to continue working with no stop, so as to notify the system or a user that the water temperature is at an improperly high point.

The present invention further provides a toilet, and the toilet comprises: the instant heating unit as described above; a water inlet pipe, the water inlet pipe being connected to the water inlet of the instant heating unit, so as to cause the washing water to flow into the instant heating unit; and a washing device, wherein the water outlet of the instant heating unit is connected to the washing device, so as to cause the heated washing water to wash.

Preferably, the toilet further comprises an inlet sensor and an outlet sensor to monitor the temperature of the washing water, and the toilet further comprises a controller, wherein the inlet sensor and the outlet sensor transmit monitored water temperature information to the controller, thereby controlling the heating power of the heating device. The toilet can comprise an independent temperature sensor that is controlled independent of the controller, so as to improve the safety of the heating system.

The present invention further provides an instant heating method used for heating washing water of a toilet by means of an instant heating unit. The instant heating method comprises: causing washing water to be heated to flow, via a water inlet of the instant heating unit, into its housing; causing the washing water to flow, via the water inlet, into an inner cavity of a hollow heating tube arranged inside the housing; causing the washing water to flow from the inner cavity to an annular gap, the annular gap being formed between the outer surface of the heating device and the inner surface of the housing; causing the washing water to flow, in the annular gap, toward a water outlet of the instant heating unit; and causing the washing water to flow out of the water outlet of the instant heating unit.

Advantageously, the instant heating method may further comprise: causing the washing water to laterally flow, through a transitioning opening formed on the housing, out of the annular gap and into a water mixing section, wherein the water mixing section is in direct communication with the water outlet. Therefore, the heated washing water can, after leaving the annular gap, not directly flow out of the water outlet, but pass through a section of mixing area, so as to improve the flexibility of channel design and increase the possibility of improving the water temperature uniformity.

In particular, the method may further comprise: causing the washing water to flow along a tortuous path for the washing water to flow in the water mixing section. By providing the tortuous flowing path, the washing water can further generate vortexes in the mixing region, thereby enhancing the temperature uniformity.

### BRIEF DESCRIPTION OF THE DRAWINGS

FIG. 1 schematically illustrates a three-dimensional exploded view of the structure of an instant heating unit according to an embodiment of the present invention;

FIGS. 2A-2B schematically illustrate a top view of the instant heating unit and a cross-sectional view of the internal structure taken along the line A-A according to an embodiment of the present invention;

FIGS. 3A-3C schematically and separately illustrate principle diagrams of annular gaps of the instant heating unit according to the embodiment of FIGS. 2A-2B, respectively;

FIGS. 4A-4B schematically and separately illustrate a side view of the instant heating unit and a cross-sectional view of the internal structure taken along the line B-B according to an embodiment of the present invention, respectively, wherein the water mixing section and the first spoiler mechanism are shown;

FIGS. 5A-5B and separately schematically illustrate an external three-dimensional view of the instant heating unit equipped with a second spoiler mechanism and a three-dimensional view of the second spoiler mechanism according to an embodiment of the present invention, respectively;

FIG. 6 schematically illustrates an external three-dimensional view of the instant heating unit equipped with an independent temperature sensor according to an embodiment of the present invention; and

FIG. 7 schematically illustrates another embodiment of the annular gap of the instant heating unit according to the present invention.

### LIST OF REFERENCE NUMBERS IN THE ACCOMPANYING DRAWINGS

100 instant heating unit;
110 housing;
112 water inlet;
114 water outlet;
116 transition opening;
120 heating device;
122 inner cavity (of the heating device);
124 longitudinal center line;
130 annular gap;
132 narrowed section;
134 small diameter section;
136 large diameter section;
140 water mixing section;
142 first spoiler mechanism;
142a baffle;
144 tortuous path;
150 second spoiler mechanism;
152 vane;
154 central shaft;
160 water-cooling heat-conducting plate;
170 controller;
180 temperature sensor;
182 water inlet sensor;
184 water outlet sensor.

### DETAILED DESCRIPTION OF THE INVENTION

It should be noted that the accompanying drawings referred to are not all drawn to scale, but may be zoomed in to illustrate various aspects of the present invention, and in this regard, the accompanying drawings should not be construed as limiting.

In the present invention, the term “toilet” refers to the entire cleaning system for flushing toilets, for example, including a seat with a sump, a toilet cover, a toilet tank, various pipes, electric wires, connectors, and fittings. However, it can be understood that the toilet of the present invention includes any module that needs to perform the function of heating washing water, but the type of the toilet of the present invention is not limited. For example, smart toilets, siphon toilets, and various conventional toilets shall all fall within the scope of the present invention.

It can be understood that although the instant heating unit of the present invention is used to heat washing water of a toilet, the instant heating unit may also be connected with other components of the toilet or other sanitary ware and equipment to heat other incoming water or discharged water.

Moreover, although the unit for heating the washing water of a toilet is referred to as an “instant heating unit” in the present invention, the instant heating unit of the present invention does not exclude any components that may be present for storing hot washing water. That is to say, the instant heating unit of the present invention at least has the function of instantly heating washing water, but may also be integrated with other heating functions.

In the text below, the length direction of the instant heating unit or the length direction of the heating device located in the instant heating unit is defined as the longitudinal direction of the instant heating unit, while a direction at an angle, in particular at a substantially right angle, to the longitudinal angle is defined as the lateral direction of the instant heating unit.

In addition, in the present invention, devices or components such as the controller 170, the temperature sensor 180, the heat conducting member, and the like may be independent of the instant heating unit but assigned to the instant heating unit, but may also be integrated with the instant heating unit (that is, a part belonging to the instant heating unit).

In order to heat the washing water of a toilet, the instant heating unit 100 of the present invention needs to be connected with a water inlet pipe and a water outlet pipe (not shown). The water inlet pipe may be a pipeline completely independent of the water inlet of the toilet, but may also be a branch pipeline of the water inlet pipe of the toilet. A water outlet pipe (not shown) is typically connected to a washing device, such as its washing nozzle, to provide heated water for a user to wash.

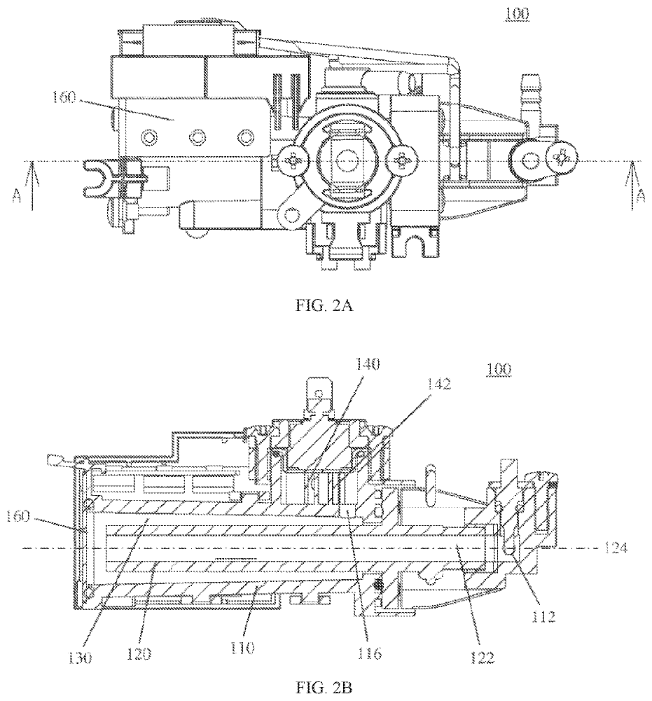

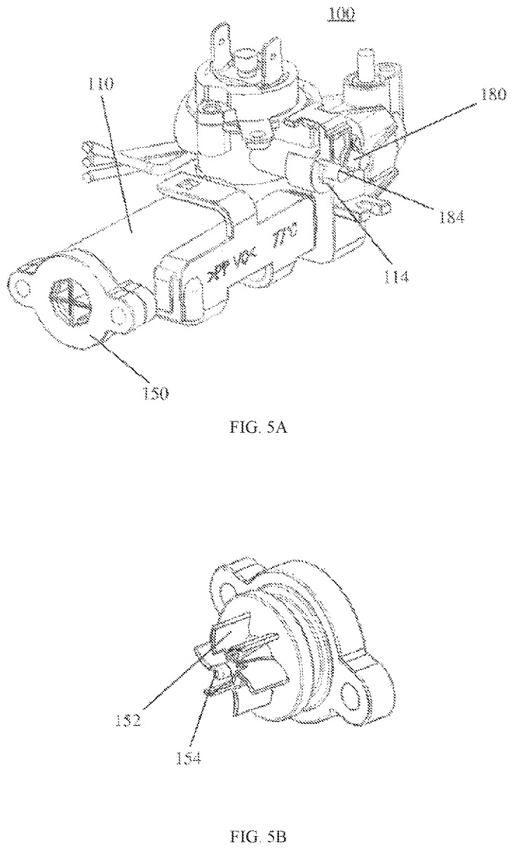

Therefore, the instant heating unit 100 according to the present invention comprises a housing 110, a water inlet 112, and a water outlet 114 (shown in FIG. 5A) to be connected with the above-mentioned water inlet pipe and water outlet pipe (not shown), respectively. Housing 110 is preferably generally cylindrical, and may also include other structures extending from the cylindrical structure. As schematically shown in FIG. 2B, the water inlet 112, and the water outlet 114 may be formed at different locations on the housing 110. It can be understood that the washing water to be heated flows into the housing 110 through the water inlet 112, while the heated washing water flows out of the housing 110 through the water outlet 114, for example, to the above-described washing device. According to the present invention, there are usually one water inlet 112 and one water outlet 114 on the instant heating unit 100, but it is not excluded that multiple water inlets 112 and/or multiple water outlets 114 may be included, so as to provide different inlet and outlet water flow paths or locations, which, for example, may lead to a different outlet pipe (not shown) when not used for a water spraying device.

In order to realize the heating function, the instant heating unit 100 comprises a heating device 120, and the heating device 120 is arranged inside the housing of the instant heating unit 100. The heating device 120 is at least capable of heating water flowing over its outer surface (for example, a heating element of the heating device 120 is near or at the outer surface). Preferably, the heating device 120 may also heat water flowing through its interior. In the present invention, the heating device 120 can be configured as a heating tube, in particular a hollow heating tube. Therefore, the heating device 120 defines an inner cavity 122 and a longitudinal center line 124.

Preferably, the longitudinal center line 124 of the heating device 120 coincides with the longitudinal center line of the inner cavity of the housing 110 of the instant heating unit 100. In other words, the location of the heating device 120 inside the housing 110 of the instant heating unit 100 is designed to be centered. However, the heating device 120 may also be arranged eccentrically with respect to the inner cavity of the housing 110 of the instant heating unit 100.

In the present invention, the washing water flowing into the housing 110 of the instant heating unit 100 through the water inlet 112 will flow into the heating device 120, that is, the inner cavity 122 of the hollow heating tube, as shown in FIG. 2B. The washing water may be preheated in the inner cavity 122 of the heating device 120, for example, to have the temperature raised by 1-2 degrees Celsius, but may also not be preheated, in which case it only flows through the inner cavity 122. In addition, when the heating device 120 does not include an inner cavity, the washing water may also not flow into the inner cavity, but directly into the annular gap 130 to be described in detail below.

The size of the heating device 120 can be determined according to various requirements, but the size of the inner cavity 122 of the heating device 120 is generally large, so that a large amount of heated water can be obtained (which avoids a situation of heating without water). In this case, even if the water is cut off, the danger of heating without water by the instant heating unit 100 will not easily occur. After each water outage or power failure, the washing water accumulated in the instant heating unit 100 preferably needs to be emptied, so as to avoid various hygienic issues that tend to be caused by accumulated water.

According to the present invention, an annular gap 130 will be formed between the outer surface of the heating device 120 and the inner surface of the housing 110. Here, the term “annular gap” refers to a three-dimensional space formed between the outer surface of the heating device 120 and the inner surface or inner wall of the housing 110, and is referred to as an annular gap because the gap has an annular shape surrounding the heating device. The “width” of the “annular gap” may refer to the distance dimension (the dimension in the radial direction) between the outer surface of the heating device 120 and the inner surface or inner wall of the housing 110.

Preferably, the heating device 120 may be arranged inside the housing 110 in such a manner that the gap width in each cross section (i.e., each of countless sections perpendicular to the longitudinal center line) of the annular gaps 130 along its longitudinal center line (regardless of whether it is the longitudinal center line of the inner cavity 122 of the heating device 120 or the inner cavity of the housing 110) is circumferentially uniform. In short, in this embodiment, when viewed from any cross section, the ring width of the annular gap 130 is always uniform in the circumferential direction. However, it can be understood that the width dimension of the annular gap 130 may be different or may be the same when viewed from different cross sections along the longitudinal center line.

According to the present invention, after passing through the inner cavity 122 of the heating device 120, the washing water will flow to the annular gap 130 of the instant heating unit 100. Here, the washing water can flow directly into the annular gap 130 after flowing through the inner cavity 122 of the heating device 120, but it may also flow into the annular gap 130 after passing through other components or channels. In the embodiment shown in FIG. 2B, the washing water flows in through the water inlet 112 on the right side of the figure, then flows through the inner cavity 122 of the heating device 120 in a right-to-left direction, and then directly flows into the annular gap 130 again at the left end thereof. In the annular gap 130, the washing water flows from left to right. In some embodiments, the annular gap 130 does not extend over the entire longitudinal length of heating device 120, but only over a portion of its length. However, the latter is also conceivable.

When the washing water flows through the annular gap 130, since the annular gap 130 is defined by the outer wall (outer surface) of the heating device 120 and the inner wall (inner surface) of the housing 110 of the instant heating unit 100, the washing water is divided into a portion relatively closer to the fixed surface (also referred to as a “side portion”) and a portion relatively further away from the fixed surface (also referred to as a “center portion”). Since the flow velocity of the center portion of the washing water passing through the annular gap 130 is higher than the flow velocity of the two sides (the water flow of the washing water close to the solid surface is decelerated due to the adhesion of the fixed surface, so that the flow velocity in the center is greater than the flow velocity on both sides), so small vortexes (self-disturbances) are generated in the water due to the flow velocity difference, which can cause the heating of the washing water to be more thorough and more uniform. In particular, the size of the annular gap 130 is designed to be small enough to enable the washing water flowing to the outlet via the narrowed section 132 to generate vortexes sufficient to cause the heating to be uniform. Preferably, the size of the annular gap 130 may be 2 to 5 mm, such as 2.5, 3.0, 3.5, 4.0, or 4.5 mm.

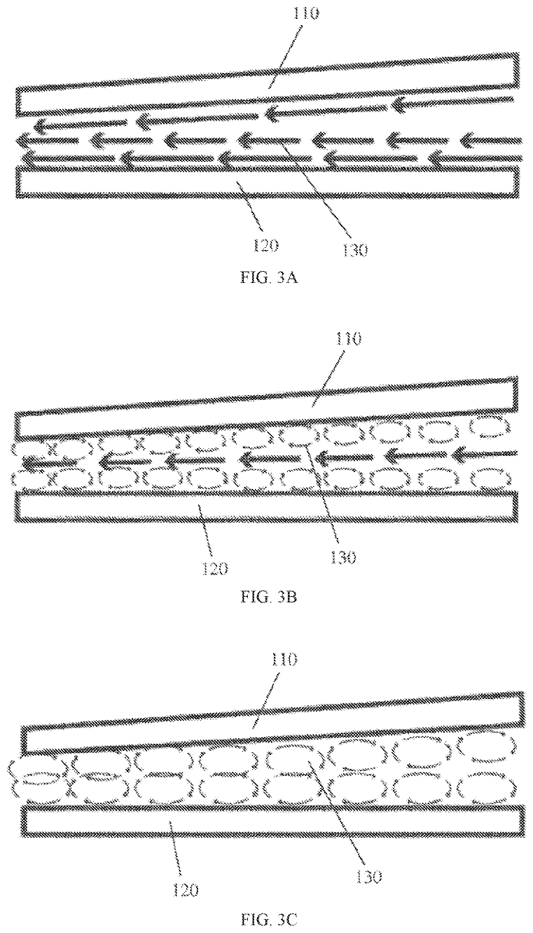

As shown in FIGS. 3A-3C, it is particularly advantageous that the annular gap 130 described above may comprise a narrowed section. The cross section of the narrowed section is designed to narrow in a direction toward the water outlet 114 along the longitudinal direction of the instant heating unit 100. The narrowed section can be located anywhere along the longitudinal direction of the annular gap 130. However, it is also conceivable that the entire annular gap 130 is configured to narrow towards the water outlet 114. When the annular gap 130 comprises a narrowed section, the small vortexes generated when the washing water flows through can be more thoroughly mixed, thereby increasing the turbulence amplitude and then causing the heating of the washing water to be more uniform.

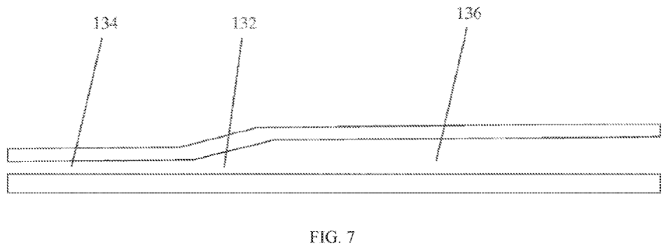

In the embodiment of FIGS. 3A-3C, the cross section of the narrowed section is longitudinally designed to be continuously narrowed in the direction toward the water outlet 114 (see also FIG. 2B). More preferably, the length of the narrowed section 132 is as long as possible, that is, the continuous narrowing range is as long as possible (for example, from one end of the housing 110 of the instant heating unit 100 to the other end thereof), so that a uniform and continuous small slope can be obtained, which is favorable for both turbulence and more uniform heating. However, it is also conceivable that the cross section of the narrowed section 132 is narrowed discontinuously, for example, in a stepped manner or intermittently. In the case of continuous narrowing, the cross section of the narrowed section 132 can be uniformly narrowed, that is, the narrowing slope remains the same along the longitudinal direction, but it may also be that the narrowing slope is variable, for example, the narrowing slope toward the water outlet 114 is large first and then becomes small, or is small first and then becomes big, or the like. In another embodiment as shown in FIG. 7, the annular gap includes a narrowed section 132 and a non-narrowed section, the non-narrowed section comprising a large diameter section 136 (the right section in the figure) and a small diameter section 134 (the left side section in the figure), while the narrowed section 132 is located between the large diameter section 136 and the small diameter section 134. As can be seen from FIG. 7, in this embodiment, the narrowing in the narrowed section 132 is still uniform narrowing, that is, the slope remains the same.

Preferably, the flow direction of the washing water in the inner cavity 122 of the heating device 120 is exactly opposite to the flow direction of the washing water in the annular gap 130. However, it is also conceivable that the flow directions of the two are the same or at an angle, depending on the arrangement of the outer wall (outer surface) of the heating device 120 and the inner wall (inner surface) of the housing 110 of the instant heating unit 100 (for example, there are still other intermediate elements in the annular gap 130, so as to cause the flow directions to be not substantially parallel and opposite to each other) or whether there are other deflection structures (for example, for the washing water flowing out of the inner cavity 122 to be deflected before entering the annular gap 130) between the heating device 120 and the inner wall of the housing 110.

In addition, a transition opening 116 may also be formed or opened on the housing 110 of the instant heating unit 100, and the transition opening 116 is used for the heated washing water to leave the annular gap 130, which has, nevertheless, not yet flowed out of the instant heating unit 100 through the water outlet 114. As shown in FIG. 2B, the transition opening 116 is provided on one side, for example, the upper side, of the housing 110. Therefore, the heated washing water leaves the annular gap 130 laterally via the laterally arranged transition opening 116.

Before the heated washing water leaves the instant heating unit 100 through the water outlet 114, in order to further homogenize the temperature inside the washing water at each location, a water mixing section 140 may be provided in the housing 110 of the instant heating unit 100. One end of the water mixing section 140 is in communication with the transition opening 116, and the other end is in communication with the water outlet 114, so that the washing water leaves the annular gap 130 laterally through the transition opening 116 and enters the water mixing section 140, and then flows to the water outlet 114.

So far, in the embodiment shown in FIG. 2B, the flow path of the washing water from the water inlet 112 to the water outlet 114 is as follows: entering the housing 110 via the water inlet 112, flowing through the inner cavity 122 of the heating device 120, turning and entering the annular gap 130, flowing into the water mixing section 140 via the transition opening 116, and finally leaving the housing 110 from the water outlet 114 to a subsequent, for example, washing device.

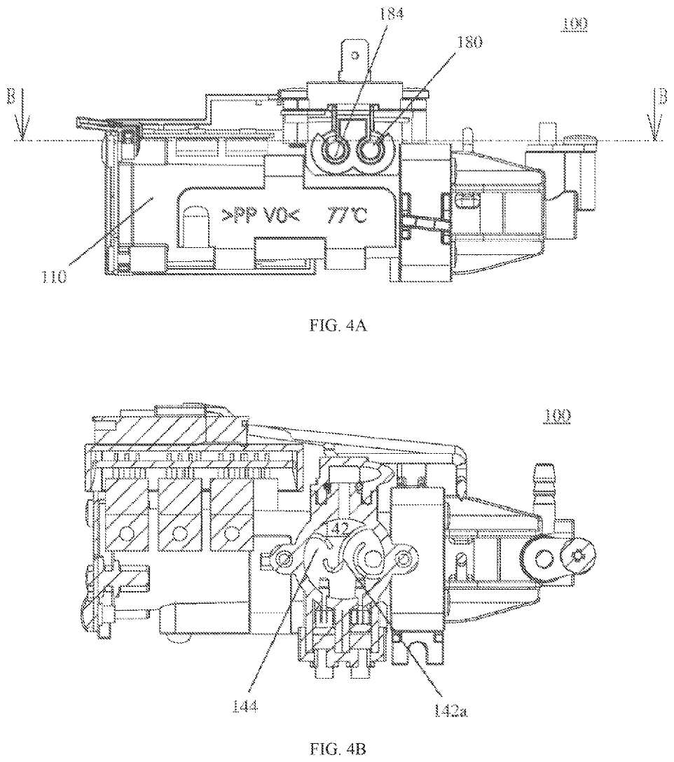

As clearly shown in FIG. 4B, the water mixing section 140 of the present invention may be provided with a first spoiler mechanism 142 to increase vortexes or turbulence inside the washing water, thereby causing the water temperature to be more uniform. As shown in FIG. 4B, in a preferred embodiment, the first spoiler mechanism 142 is provided as a baffle 142a that can define a tortuous path 144 for the washing water to flow inside the water mixing section 140. In other words, the heated washing water entering the water mixing section 140 does not flow directly into the water outlet 114, but flows along the tortuous path 144 in the water mixing section 140, and finally flows to the water outlet 114. In order to form such a tortuous path 144, at least one and preferably a plurality of baffles are arranged in the water mixing section 140. Of course, these baffles 142a are only used to block the washing water from directly flowing to the water outlet 114, but do not fully block the washing water from flowing out.

For example, the baffle 142a may extend from a location on the inner wall of the water mixing section 140 toward the center of the water mixing section 140, or even to areas close to other locations in the inner wall. Preferably, the baffle 142a is a curved baffle, so as to facilitate the washing water to further form vortexes or turbulent flows. As shown in FIG. 4B, in the preferred embodiment, the water mixing section 140 is provided with a plurality of opposed curved baffles 142a that form a tortuous flow path from the transition opening 116 to the water outlet 114.

It can be understood that the more tortuous the tortuous path 144 and the longer the flow path, the more fully the heated washing water is mixed there. It should also be noted, however, that longer flow paths are not always better, as the water temperature drops if the heated washing water stays in the water mixing area for too long, which is not desirable. The first spoiler mechanism 142 of the present invention may also comprise any other types of deflection elements, such as flexible or elastic deflection rods or deflection bars.

In addition, the instant heating unit 100 according to the present invention may further comprise a second spoiler mechanism 150 for generating vortexes or turbulent flows, thereby enhancing the uniformity of water temperature of the washing water. When the second spoiler mechanism 150 is attached to the end of the housing 110 of the instant heating unit 100 of the present invention, the instant heating unit 100 may be referred to as an enhanced instant heating unit 100. Preferably, the second spoiler mechanism 150 is arranged at or close to the end of the housing 110 of the instant heating unit 100 away from the water inlet 112. As shown in FIG. 5A, the second spoiler mechanism 150 is arranged at an end of the housing 110 that is opposite to the water inlet 112.

Preferably, as shown in FIG. 5B, the second spoiler mechanism 150 may comprise vanes 152, and the washing water leaving the inner cavity 122 of the heating device 120 may first hit the vanes 152 and then flow to the annular gap 130. Through this flushing, the washing water is deflected in its direction and also generates mixed vortexes, and therefore, the heating uniformity of the washing water having vortexes when flowing through the annular gap 130 can be significantly improved.

In addition, the second spoiler mechanism 150 may comprise a central shaft 154 that may or may not coincide with the longitudinal center line of the housing 110 or the heating device 120. The plurality of vanes 152 of the second spoiler mechanism 150 are advantageously fixed to this central shaft 154 for distribution around the central shaft 154. Preferably, these vanes 152 themselves are also curved, for example, they may be curved in the same direction, but not limited thereto. Alternatively, the vanes 152 are helical vanes, so that the washing water generates a helical flow after passing through the second spoiler mechanism 150. In addition, the vanes 152 of the second spoiler mechanism 150 of the present invention may be stationary, but may also be designed to move with the water flow, for example, to rotate.

In addition, the central shaft 154 may be fixed to the housing of the second spoiler mechanism 150 and cannot be rotated. However, in other embodiments, the central shaft may also be rotated to drive the vanes 152 to rotate. The rotational drive of the central shaft may be driven by a drive mechanism of the second spoiler mechanism 150, but may also be driven by passive rotation caused by the impact of the washing water on the vanes 152.

In addition to the above-mentioned first spoiler mechanism 142 and second spoiler mechanism 150, the instant heating unit 100 of the present invention may further comprise other spoiler mechanisms for assisting in generating vortexes to enhance the heating uniformity. For example, the other spoiler mechanisms may be high-frequency vibrating elements that use vibration to generate fluctuations.

The instant heating unit 100 according to the present invention typically comprises a controller 170, and the controller 170 is mainly used for controlling the heating power and the like of the washing water. The controller 170 typically comprises a control circuit, and the control circuit usually has high temperature and requires special cooling devices.

In the present invention, it is advantageous to use the washing water as a medium for cooling the control circuit. This is because although the washing water is heated by the heating device in the instant heating unit 100, it is only heated to twenty-plus degrees Celsius, which is a comfortable temperature for human body and still belongs to the category of cooling water temperature with respect to the temperature of the control circuit that is greater than 60 degrees Celsius.

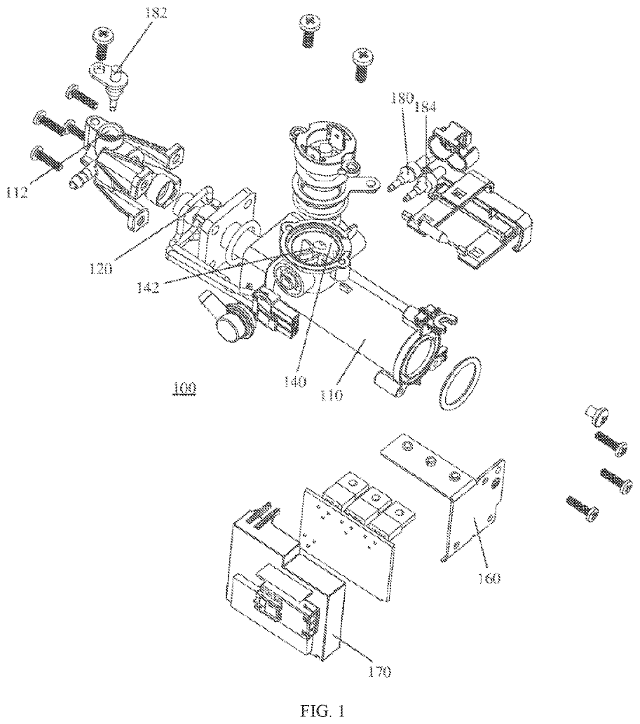

To this end, it is preferable that a water-cooling heat-conducting plate 160, a heat-conducting block, or other similar elements are attached to the housing 110 of the instant heating unit 100, as schematically shown in FIG. 2B. The water-cooling heat-conducting plate 160 can be in contact with the control circuit, and at the same time, the low-temperature washing water is also in direct contact with the water-cooling heat-conducting plate 160, so that the heat of the control circuit can be dissipated through the water-cooling heat-conducting plate 160, thereby achieving the goal of controlling the temperature within a reasonable range. Preferably, the water-cooling heat-conducting plate 160 may be installed at an end of the housing 110 of the instant heating unit 100 that is opposite to the water inlet 112. As clearly shown in FIG. 1, the water-cooling heat-conducting plate 160 may be L-shaped to increase the surface area in contact with the washing water and improve the heat dissipation efficiency. However, a water-cooling heat-conducting plate 160 of other shapes or structures may also be conceived in the present invention.

As can be seen from FIG. 1, when the water-cooled heat conduction plate 160 is attached to the housing 110 of the instant heating unit 100, the instant heating unit 100 is not provided with the above-described second spoiler mechanism 150. However, it is also conceivable that the instant heating unit 100 is provided simultaneously with these two devices, for example, the water-cooling heat-conducting plate 160 extends only in the longitudinal direction, while the second spoiler 150 is still provided at a longitudinal end.

In addition, in order to improve the safety of the instant heating unit 100 of the present invention, the instant heating unit 100 may also advantageously comprise a temperature safety device. The temperature safety device may comprise at least one independent temperature sensor 180. When the temperature sensor 180 detects that the temperature of the washing water exceeds a preset temperature, the temperature safety device can stop the washing water from entering the instant heating unit 100. Advantageously, the power supply, for example, that of a water inlet valve, can be cut off directly in the electric circuit, thereby shutting off the water supply (i.e., the washing water no longer enters the instant heating unit). Since this circuit does not need to go through an MCU (for example, a heating power controller), even if there is a software problem, it will not affect the normal operation of this circuit.

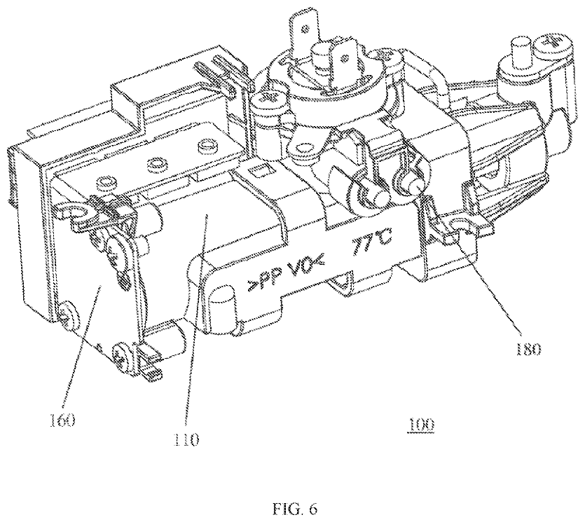

Advantageously, the independent temperature sensor 180 is disposed to be close to the water outlet 114 of the housing 110, for example, at the water mixing section 140 (i.e., in the upper area of the housing 110 shown in FIG. 6).

The so-called independent temperature sensor 180 refers to temperature sensors other than the water inlet sensor 182 and the water outlet sensor 184 that the instant heating unit 100 usually has, and more importantly, the independent temperature sensor 180 is controlled independent of the above-described controller 170 (the controller 170 is mainly used for controlling the heating power). This independence can ensure that when the thyristor circuit of the controller 170 is broken down by a large current that causes the heating device 120 to continue working with no stop, the temperature sensor 180 can still send an alarm to notify the system or a user that the water temperature is at an improperly high point. As a result, when the controller 170 itself fails, the independent temperature sensor 180 can still sense the high water temperature and then cut off the washing water supplied to the user, so as to prevent safety accidents such as scalding.

While various embodiments of the present invention have been described in the various figures with reference to the embodiments of a toilet that comprises an instant heating unit, it should be understood that the embodiments within the scope of the present invention are applicable to equipment, in particular sanitary ware and equipment, with similar heating structures and/or heating functions other than the instant heating unit in a toilet.

The foregoing description has given numerous features and advantages, including various alternative implementations, as well as details of the structures and functions of the devices and methods. This text is intended to be exemplary, rather than exhaustive or limiting.

It will be obvious to those skilled in the art that various modifications may be made within the full scope indicated by the broad and superordinate meaning of the terms expressed in the appended claims, particularly in aspects of structures, materials, elements, parts, shapes, dimensions, and component arrangements, including combinations of these aspects within the scope of the principles described herein. To the extent that these various modifications do not depart from the spirit and scope of the appended claims, they are intended to be encompassed herein as well.

1. An instant heating unit (100) for heating washing water of a toilet, the instant heating unit (100) comprising
a housing (110) having a water inlet (112) and a water outlet (114), configured for washing water to be heated flowing into the housing (110) through the water inlet (112) and flowing out of the housing (110) through the water outlet (114); and
a heating device (120), the heating device being of a hollow tube shape, arranged inside the housing (110), and extending along the longitudinal direction of the housing (110);
wherein an annular gap (130) is formed between the outer surface of the heating device (120) and the inner surface of the housing (110), the washing water configured to flow into the interior of the heating device (120) from the water inlet (112), to flow from the interior of the heating device to the annular gap (130), and to flow out of the water outlet (114) through the annular gap (130).

2. The instant heating unit (100) according to claim 1, wherein an inner cavity (122) and a longitudinal center line (124) are defined inside the heating device, and the washing water is configured to flow into the inner cavity.

3. The instant heating unit (100) according to claim 2, wherein the heating device is arranged at the center in the housing (110), so that the gap width of the annular gap (130) is circumferentially distributed in a uniform manner in each cross section along the longitudinal center line.

4. The instant heating unit (100) according to claim 1, wherein the annular gap (130) comprises a narrowed section (132), and the gap width of the narrowed section narrows down along the longitudinal direction of the housing and towards the water inlet (112).

5. The instant heating unit (100) according to claim 4, wherein the gap width of the narrowed section continuously and uniformly narrows down along the longitudinal direction and towards the water inlet (112).

6. The instant heating unit (100) according to claim 4, wherein the size of the annular gap (130) is in a range of 2 to 5 mm, so that vortexes are generated in the washing water that flows to the water outlet (114) via the narrowed section.

7. The instant heating unit (100) according to claim 1, wherein the heating device is arranged such that the flowing direction of the washing water therein is opposite to the flowing direction thereof in the annular gap (130).

8. The instant heating unit (100) according to claim 1, wherein the housing (110) further comprises a transitioning opening (116) and a water mixing section (140), the washing water is configured to laterally leave, through the transitioning opening (116), the annular gap (130) and enter the water mixing section (140), and the water mixing section (140) is in direct communication with the water outlet (114).

9. The instant heating unit (100) according to claim 8, wherein a first spoiler mechanism (142) is provided in the water mixing section (140), and the first spoiler mechanism (142) comprises a baffle (142a) capable of defining a tortuous path (144) for the washing water to flow in the water mixing section (140).

10. The instant heating unit (100) according to claim 1, wherein the instant heating unit (100) further comprises a second spoiler mechanism (150), the second spoiler mechanism (150) comprises vanes (152), and the washing water that leaves the interior of the heating device hits the vanes (152) and flows to the annular gap (130).

11. The instant heating unit (100) according to claim 10, wherein the second spoiler mechanism (150) is arranged at or close to an end of the housing (110) of the instant heating unit (100) that is away from the water inlet (112).

12. The instant heating unit (100) according to claim 10, wherein the vanes (152) of the second spoiler mechanism (150) can be rotated.

13. The instant heating unit (100) according to claim 1, wherein a water-cooling heat-conducting plate (160) capable of contacting the washing water inside the housing (110) is attached to the instant heating unit (100), and the water-cooling heat-conducting plate (160) is used for heat dissipation for a control circuit.

14. The instant heating unit (100) according to claim 1, wherein the instant heating unit (100) comprises an independent temperature safety device, the temperature safety device comprises a temperature sensor (180), and when the temperature sensor (180) detects that the temperature of the washing water exceeds a preset temperature, the temperature safety device can stop the washing water from entering the instant heating unit (100).

15. A toilet, comprising
the instant heating unit (100) according to claim 1;
a water inlet pipe, the water inlet pipe connected to the water inlet (112) of the instant heating unit (100), so as to cause the washing water to flow into the instant heating unit (100); and
a washing device, wherein the water outlet (114) of the instant heating unit (100) is connected to the washing device, so as to cause the heated washing water to wash.

16. The toilet according to claim 15, wherein the toilet further comprises an inlet sensor (182) and an outlet sensor (184) to monitor a temperature of the washing water, and the toilet further comprises a controller (170), wherein the inlet sensor and the outlet sensor transmit monitored water temperature information to the controller (170), thereby controlling the heating power of the heating device.

17. An instant heating method for heating washing water of a toilet by means of the instant heating unit (100) according to claim 1, comprising
causing washing water to be heated to flow, via a water inlet (112) of the instant heating unit (100), into housing (110);
causing the washing water to flow, via the water inlet (112), into a hollow tubular heating device arranged inside the housing (110);
causing the washing water to flow from the interior of the heating device to an annular gap (130), the annular gap (130) being formed between the outer surface of the heating device and the inner surface of the housing (110); and
causing the washing water to flow out of the water outlet of the instant heating unit (100) through the annular gap (130).

18. The instant heating method according to claim 17, wherein the instant heating method further comprises causing the washing water to laterally flow, through a transitioning opening (116) formed on the housing (110), out of the annular gap (130), and into a water mixing section (140), wherein the water mixing section (140) is in direct communication with the water outlet (114).

19. The instant heating method according to claim 17, wherein the method further comprises causing the washing water to flow along a tortuous path (144) for the washing water to flow in the water mixing section (140).
